(19) United States
(12) Patent Application Publication
(10) Pub. No.: US 2009/0152741 A1
(43) Pub. Date: Jun. 18, 2009

(54) CHIP STRUCTURE AND FABRICATION PROCESS THEREOF AND FLIP CHIP PACKAGE STRUCTURE AND FABRICATION PROCESS THEREOF

(75) Inventors: Tao-Chih Chang, Taoyuan County (TW); Chao-Kai Hsu, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/192,138

(22) Filed: Aug. 15, 2008

(30) Foreign Application Priority Data
Dec. 12, 2007 (TW) 96147454

(51) Int. Cl. H01L 21/768; H01L 23/488

(52) U.S. Cl. 257/778; 438/612; 257/E23.023; 257/E21.59

(57) ABSTRACT

A chip structure including a chip, a first dielectric layer and at least one first conductive layer is provided. The chip has an active surface, a backside and at least one bonding pad disposed on the active surface. The first dielectric layer is disposed on the active surface and has at least one first opening, wherein the first opening correspondingly exposes the bonding pad. The first conductive layer covers an inner wall of the first opening and the bonding pad so as to form a concave structure in the first opening. When the chip structure is bonded to a substrate, the solder bump of the substrate is inlaid into the concave structure of the chip. Moreover, a fabrication process of the chip structure, a flip chip package structure and a fabrication process thereof, a package structure of a light emitting/receiving device and a chip stacked structure are also provided.

### CROSS-REFERENCE TO RELATED APPLICATION

This application claims the priority benefit of Taiwan application serial no. 96147454, filed on Dec. 12, 2007. The entirety of the above-mentioned patent application is hereby incorporated by reference herein and made a part of specification.

### BACKGROUND OF THE INVENTION

1. Field of Invention

The present invention relates to a chip package technology and more particularly to a chip package technology applied to a flip chip package.

2. Description of Related Art

A variety of chip package techniques are developed as the degree of integration of integrated circuits is increased. Flip chip (FC) bonding technology is widely applied to the chip package area such as a chip scale package (CSP) due to the advantages of small chip package volume and short signal transmission path.

In terms of the flip chip bonding technology, a plurality of bonding pads are disposed on an active surface of a chip in an area-array configuration, and solder bumps are disposed on the bonding pads. Thereafter, the chip is flipped over and a solder reflow process is performed so that the chip is bonded to the substrate via the solder bumps of the chip and the corresponding solder bumps of the substrate; hence, the chip is electronically and mechanically connected to the substrate. During the solder reflow process, the solder bumps of the chip and the corresponding solder bumps of the substrate are soldered and connected to each other. In order to prevent the adjacent solder bumps of the chip or the adjacent solder bumps of the substrate from connection caused by the soldering after the solder reflow process, an adequate pitch between the adjacent bonding pads of the chip is required.

Furthermore, a heat stress occurs between the chip and the substrate due to the different coefficients of heat expansion. Therefore, an underfill layer is filled between the chip and the substrate and encapsulates the solder bumps of the chip to prevent the solder bumps of the chip from being cracked laterally when sustaining a repeated heat stress.

In terms of the chip scale package applied to the flip chip bonding technology, the types of the chip scale package are varied, wherein a wafer-level chip scale package (WLCSP) based on a wafer has been proposed. In WLCSP, a redistribution layer (RDL) is fabricated on the surface of the chip to redistribute the bonding pads originally positioned in the periphery of the chip into an array configuration with a larger pitch corresponding to the layout of a printed circuit board (PCB). In addition, solder balls are attached to the bonding pads of the chip manually or automatically so that the bonding pads of the chip are electrically connected to the contacts on the PCB through the solder balls.

### SUMMARY OF THE INVENTION

The present invention provides a chip structure. The structure includes a chip, a first dielectric layer and at least one first conductive layer. The chip has an active surface, a backside, and at least one bonding pad, wherein the bonding pad is disposed on the active surface. The first dielectric layer is disposed on the active surface and has at least one first opening, wherein the first opening correspondingly exposes the bonding pad. The first conductive layer covers an inner wall of the first opening and the bonding pad so as to form a concave structure in the first opening.

The present invention also provides a fabrication process of a chip structure. First, a chip is provided. The chip has an active surface, a backside and at least one bonding pad, wherein the bonding pad is disposed on the active surface. Thereafter, a first dielectric layer is formed on the active surface of the chip. At least one first opening is then formed in the first dielectric layer, wherein the first opening correspondingly exposes the bonding pad. Afterwards, at least one first conductive layer is formed on an inner wall of the first opening and the bonding pad so as to form a concave structure in the first opening.

The present invention further provides a flip chip package structure. The flip chip package structure includes a substrate, at least one solder bump, a chip, a first dielectric layer and at least one first conductive layer. The substrate has a carrying surface, wherein at least one contact pad is disposed on the carrying surface. The solder bump is disposed on the contact pad of the substrate. The chip is disposed on the carrying surface and includes an active surface and at least one bonding pad, wherein the bonding pad is disposed on the active surface and corresponds to the solder bump. The first dielectric layer is disposed between the chip and the substrate and has at least one first opening, wherein the first opening correspondingly exposes the bonding pad of the chip. The first conductive layer covers an inner wall of the first opening and the bonding pad so as to form a concave structure in the first opening, wherein the solder bump is inlaid into the concave structure.

The present invention further provides a fabrication process of a flip chip package. First, a chip is provided. The chip has an active surface and at least one bonding pad, wherein the bonding pad is disposed on the active surface. Thereafter, a first dielectric layer is formed on the active surface of the chip. At least one first opening is then formed in the first dielectric layer, wherein the first opening exposes the bonding pad. Further, at least one first conductive layer is formed on an inner wall of the first opening and the bonding pad so as to form a concave structure in the first opening. Then, a substrate is provided. The substrate has a carrying surface, wherein at least one contact pad is disposed on the carrying surface and a solder bump is disposed on the contact pad. Afterwards, the active surface of the chip is disposed toward the carrying surface of the substrate so that the solder bump is inlaid into the concave structure. Then, the first dielectric layer is cured.

The present invention further provides a package structure. The package structure includes a substrate, at least one solder bump, a light emitting/receiving device, a first dielectric layer and at least one first conductive layer. The substrate has a first portion and the second portion, wherein the first portion has a carrying surface and at least one contact pad is disposed on the carrying surface. The solder bump is disposed on the contact pad of the substrate. The light emitting/receiving device is disposed on the active surface and has an active area, at least one bonding pad and a light signal input/output region, wherein the bonding pad is disposed on the active area and corresponds to the solder bump, and the light signal input/output region is used for emitting or receiving light and corresponds to the second portion. The first dielectric layer is disposed between the light emitting/receiving device and the substrate and has at least one first opening, wherein the first opening correspondingly exposes the bonding pad of the light emitting/receiving device. The first conductive layer covers an inner wall of the first opening and the bonding pad so as to form a concave structure, wherein the solder bump is inlaid into the concave structure.

The present invention further provides a chip stacked structure including a plurality of chip structures. Each of the chip structures includes a chip, a first dielectric layer, at least one first conductive layer and at least one conductive pillar. The chip has an active surface, a backside, at least one third opening and at least one bonding pad, wherein the bonding pad is disposed on the active surface and the third opening is disposed in the backside to expose the bonding pad. The first dielectric layer is disposed on the active surface and has at least one first opening, wherein the first opening correspondingly exposes the bonding pad. The first conductive layer covers an inner wall of the first opening and the bonding pad so as to form a concave structure in the first opening. The conductive pillar is disposed in the third opening and connected to the bonding pad. The chip structures are stacked together, and each two adjacent chip structures are bonded together via the corresponding concave structure and the corresponding conductive pillar.

Without forming solder bumps on bonding pads of a chip, the chip structure in accordance with the present invention has simpler structure and lower cost. In addition, the pitch between the bonding pads can be further reduced without reserving margin for conventional solder bumps; hence, the integration of bonding pads is increased. Further, according to the fabrication process of the flip chip package of the present invention, the chip are inlaid with the substrate via the concave structures of the chip and the solder bumps of the substrate; hence, a solder reflow process is not required and the lower process temperature is resulted. Moreover, according to the flip chip package structure of the present invention, the chip is bonded to the substrate by the first dielectric layer; hence, a conventional underfill layer is not required and the shorter processing time and lower processing cost are resulted. Also, according to the package structure of the light emitting/receiving device of the present invention, the light emitting/receiving device can be attached to the substrate via the first dielectric layer so that no gap exists between the light emitting/receiving device and the substrate; hence, the light emitting/receiving device is bonded to the substrate more securely and the higher reliability is resulted. Further, according to the chip stacked structure of the present invention, chip structures are stacked together via the corresponding concave structures and the corresponding conductive pillars. Therefore, the chip structures can be stacked by performing only a compression bonding process to form the chip stacked structure. Thus, the chip stacked structure is simple, the fabricating process thereof is simplified, and the processing cost is reduced.

In order to make the aforementioned and other objects, features and advantages of the present invention comprehensible, a preferred embodiment accompanied with figures is described in detail below.

### BRIEF DESCRIPTION OF THE DRAWINGS

FIG. 1 schematically illustrates, in a cross-sectional view, a chip structure according to the first embodiment of the present invention.

FIG. 2 schematically illustrates the main fabrication processing steps of a flow chart of a chip structure according to the second embodiment of the present invention.

FIGS. 3A to 3K schematically illustrate, in a cross-sectional view, a fabrication process of a chip structure according to the second embodiment of the present invention.

FIG. 4 schematically illustrates, in a cross-sectional view, a flip chip package structure according to the third embodiment of the present invention.

FIGS. 5A to 5D schematically illustrate, in a cross-sectional view, a fabrication process of a flip chip package structure according to the fourth embodiment of the present invention.

FIG. 6 schematically illustrates, in a cross-sectional view, a package structure of a light emitting/receiving device according to the fifth embodiment of the present invention.

FIG. 7 schematically illustrates, in a cross-sectional view, the solder bump being inlaid into the first conductive layer according to another embodiment.

FIG. 8 schematically illustrates, in a cross-sectional view, a chip stacked structure according to the sixth embodiment of the present invention.

FIGS. 9A to 9D schematically illustrate, in a cross-sectional view, a fabrication process of the chip stacked structure of FIG. 8.

### DESCRIPTION OF EMBODIMENTS

### The First Embodiment

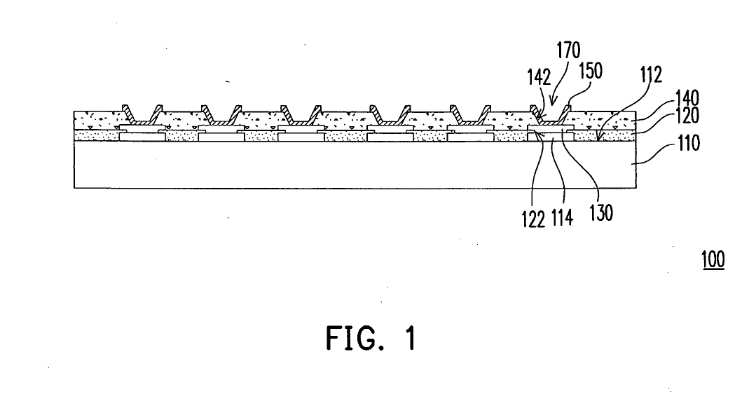

FIG. 1 schematically illustrates, in a cross-sectional view, a chip structure according to the first embodiment of the present invention. Referring to FIG. 1, a chip structure 100 mainly includes a chip 110, a first dielectric layer 140 and at least one first conductive layer 150. The chip 110 has an active surface 112 and at least one bonding pad 114. The bonding pad 114 is disposed on the active surface 112. In this embodiment, the number of the bonding pads 114 is six, which is intended to illustrate and give no limitation to the present invention.

The first dielectric layer 140 is disposed on the active surface 112 and having at least one first opening 142. The first opening 142 correspondingly exposes the bonding pad 114. The material of the first dielectric layer 140 is a B-stage (semi-cured) dielectric material, such as polyimide (PI), epoxy resin or Ajinomoto buildup film (ABF). The first dielectric layer 140 is bonded to a substrate (not shown) by heating the first dielectric layer 140; thus, the state of the first dielectric layer 140 is transformed from B-stage to C-stage so that the first dielectric layer 140 is cured and bonded to the substrate securely.

Moreover, in order to improve the dielectric effect, the chip 110 further includes a second dielectric layer 120 disposed between the active surface 112 and the first dielectric layer 140, wherein the dielectric constant of the second dielectric layer 120 is smaller than that of the first dielectric layer 140. The second dielectric layer 120 has at least one second opening 122, and the second opening 122 correspondingly exposes the bonding pad 114. Generally speaking, the moisture absorption rate of the dielectric material is getting higher as the dielectric constant of the dielectric material becomes lower. Therefore, the first dielectric layer 140 with lower moisture absorption rate, serving as a protection layer, is configured to isolate the humidity and dielectric effect from the second dielectric layer 120 with lower dielectric constant.

The first conductive layer 150 covers the inner wall of the first opening 142 and the bonding pad 114 so as to form a concave structure 170. In this embodiment, the material of the first conductive layer 150 may be different from that of the bonding pad 114. For example, the first conductive layer 150 is formed from copper while the bonding pad 114 is formed from aluminum. Therefore, the chip 100 can further include at least one second conductive layer 130 disposed between the first conductive layer 150 and the bonding pad 114. The first conductive layer 150 and the second conductive layer 130 may further be formed from the same metal material so as to provide superior bonding effect between the first conductive layer 150 and the second conductive layer 130.

### The Second Embodiment

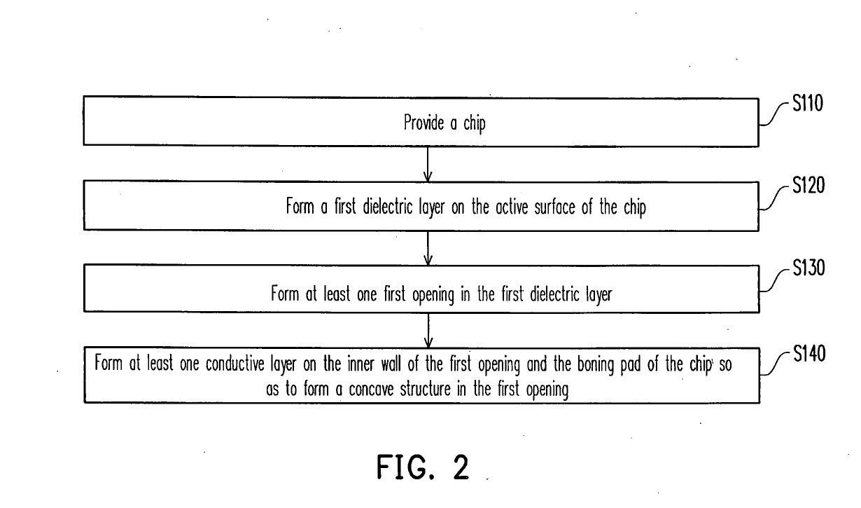

FIG. 2 schematically illustrates the main fabrication processing steps of a flow chart of a chip structure according to the second embodiment of the present invention. Referring to FIG. 2, in the fabrication process of the chip structure, at least one first opening is formed on a first dielectric layer of the chip, and a first conductive layer is formed in the first opening so as to form a concave structure. When the chip structure is bonded to a substrate, a solder bump of the substrate is inlaid into the concave structure formed by the first conductive layer; thus, the chip is electronically connected to the substrate. A detailed description is provided in the following.

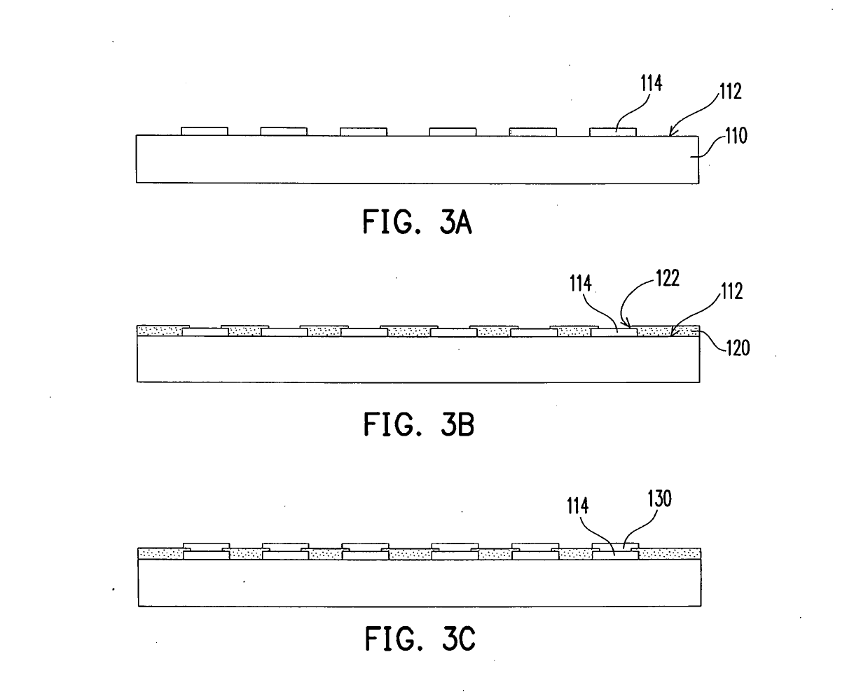

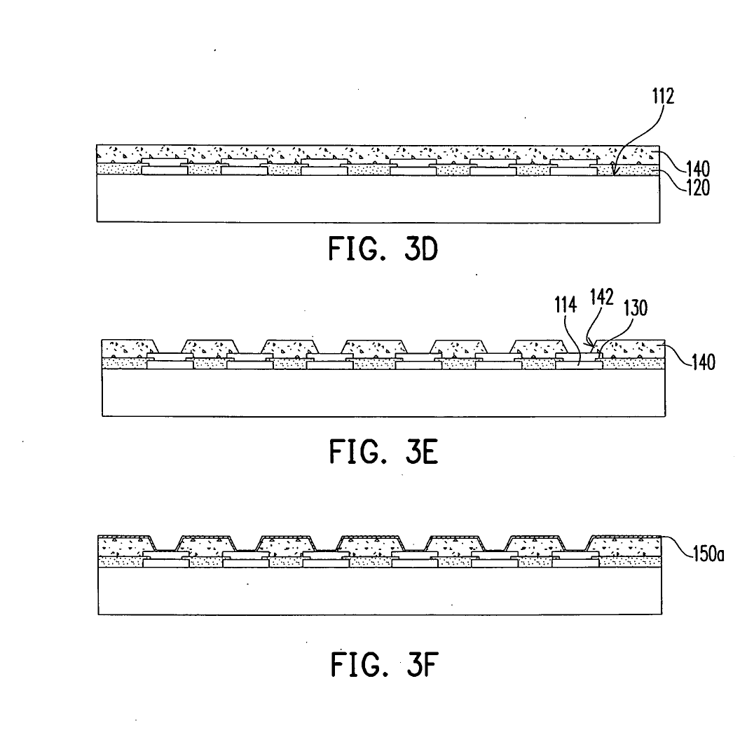

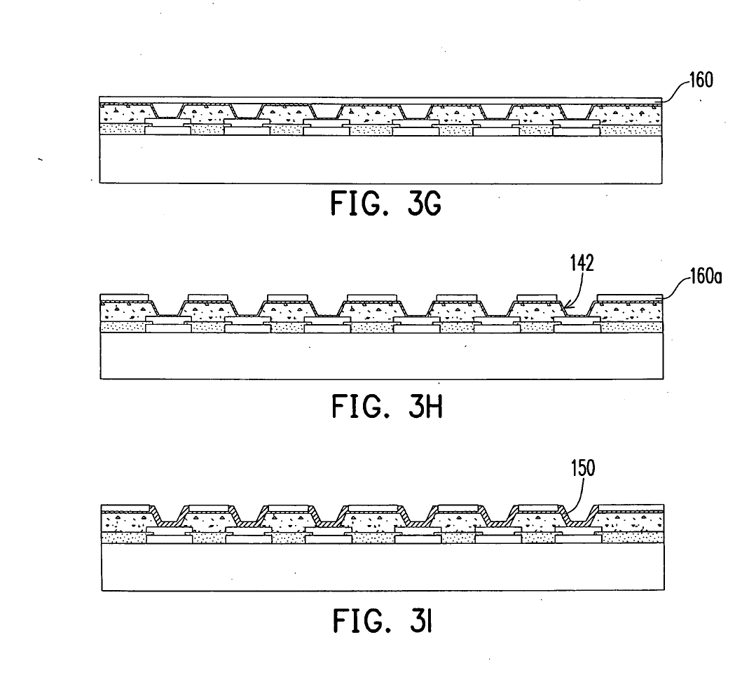

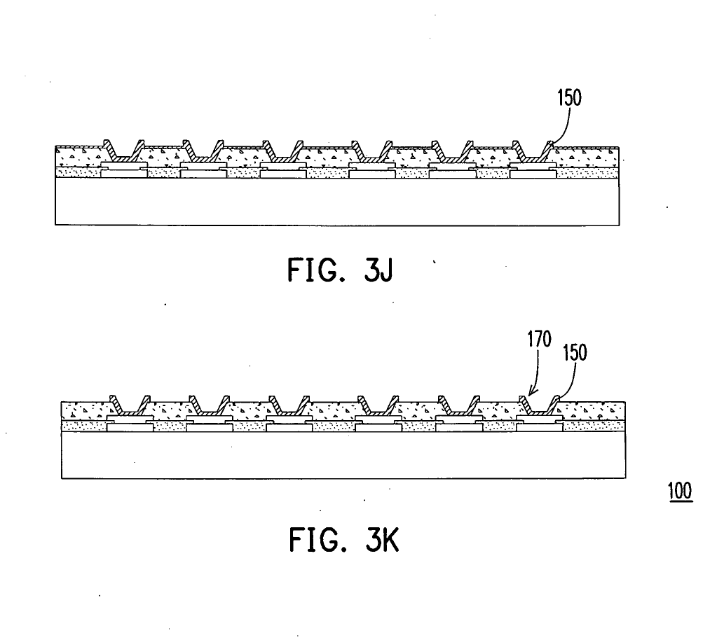

FIGS. 3A to 3K schematically illustrate, in a cross-sectional view, a fabrication process of a chip structure according to the second embodiment of the present invention. In this embodiment, the chip structure 100 of FIG. 1 is intended to illustrate and give no limitation to the present invention. The processing steps illustrated in FIG. 2 can be referred to the contents of FIGS. 3A to 3K. First, the step S110 is performed, referring to FIG. 3A, to provide a chip 110, and the chip 110 has an active surface 112 and at least one bonding pad 114. The bonding pad 114 is disposed on the active surface 112. In this embodiment, the number of the bonding pads 114 is six, which is intended to illustrate and give no limitation to the present invention. That is, the number of the bonding pads 114 can be adjusted accordingly with the number of the contacts of the chip 110 if necessary.

The fabrication process of FIGS. 3B to 3C is implemented before the step S120 is performed. Referring to FIG. 3B, a second dielectric layer 120 is formed on the active surface 112 by a manner of lamination. The second dielectric layer 120 has at least one second opening 122 to correspondingly expose the bonding pad 114. The second opening 122 is formed by performing a laser drilling to the second dielectric layer 120 after the second dielectric layer 120 is formed on the chip 110.

Referring to FIG. 3C, at least one second conductive layer 130 is formed on the bonding pad 114. The method of forming the second conductive layer 130 includes printing or electroplating. Taking the electroplating process as an example, an electroplating seeding layer (not shown) is formed on the bonding pad 114 and the second dielectric layer 120. A patterned photoresist layer (not shown) is then formed on the electroplating seeding layer. Thereafter, the patterned photoresist layer is removed. A portion of the electroplating seeding layer covered by the patterned photoresist layer is further removed to form the structure as shown in FIG. 3C.

Referring to FIG. 3D, the step S120 is performed to form a first dielectric layer 140 on the active surface 112 of the chip 110 by a manner of lamination, for example. In this embodiment, the first dielectric layer 140 is formed indirectly on the active surface 112 via the second dielectric layer 120.

The material of the first dielectric layer 140 is a B-stage dielectric material, such as polyimide (PI), epoxy resin and Ajinomoto buildup film (ABF). The first dielectric layer 140 is bonded to a substrate (not shown) by heating the first dielectric layer 140; thus, the state of the first dielectric layer 140 is transformed from B-stage to C-stage so that the first dielectric layer 140 is cured and bonded to the substrate. Generally speaking, the moisture absorption rate of the dielectric material is getting higher as the dielectric constant of the dielectric material becomes lower. Therefore, the first dielectric layer 140 with lower moisture absorption rate serves as a protection layer to isolate the second dielectric layer 120 from humidity.

Referring to FIG. 3E, the step of S130 is performed to form at least one first opening 142 in the first dielectric layer 140. The first opening 142 correspondingly exposes the second conductive layer 130 on the bonding pad 114. The first opening 142 is formed by the method of laser-drilling, for example. The glue residue caused by the laser-drilling is further removed.

Referring to FIGS. 3F to 3K, the step S140 is performed to form at least one first conductive layer 150 on the inner wall of the first opening 142 and the bonding pad 114 of the chip 110 so as to form a concave structure 170 in the first opening 142. In this embodiment, the material of the first conductive layer 150 may be different from that of the bonding pad 114. For example, the first conductive layer 150 is formed from copper while the bonding pad 114 is formed from aluminum. The second conductive layer 130 (as shown in FIG. 3C) is formed on the bonding pad 114 first, so that the first conductive layer 150 is formed indirectly on the bonding pad 114 via the second conductive layer 130. Furthermore, the first conductive layer 150 and the second conductive layer 130 may be formed from the same metal material to provide superior bonding effect between the first conductive layer 150 and the second conductive layer 130 securely.

Referring to FIG. 3F, an electroplating seeding layer 150a is formed on the first dielectric layer 140. Referring to FIG. 3G, a photoresist layer 160 is formed on the electroplating seeding layer 150a. In this embodiment, the photoresist layer 160 is a dry film photoresist attached to the electroplating seeding layer 150a, for example. In another embodiment (not shown), the photoresist layer 160 may be a liquid photoresist coated on the electroplating seeding layer 150a.

Referring to FIG. 3H, an exposure-and-development process is performed to the photoresist layer 160, so that a patterned photoresist layer 160a is formed to expose a portion of the electroplating seeding layer 150a corresponding to the first opening 142. Referring to FIG. 3I, an electroplating process is performed, using the patterned photoresist layer 160a as a mask, to the electroplating seeding layer 150a so as to form the first conductive layer 150 which is thicker than the electroplating seeding layer 150a. Referring to FIG. 3J, the patterned photoresist layer 160a (as shown in FIG. 3I) is removed. Referring to FIG. 3K, an etching process is then performed to remove the portion of the electroplating seeding layer 150a covered by the patterned photoresist layer 160a (as shown in FIG. 3I), so that the chip structure 100 having the concave structure 170 is formed.

### The Third Embodiment

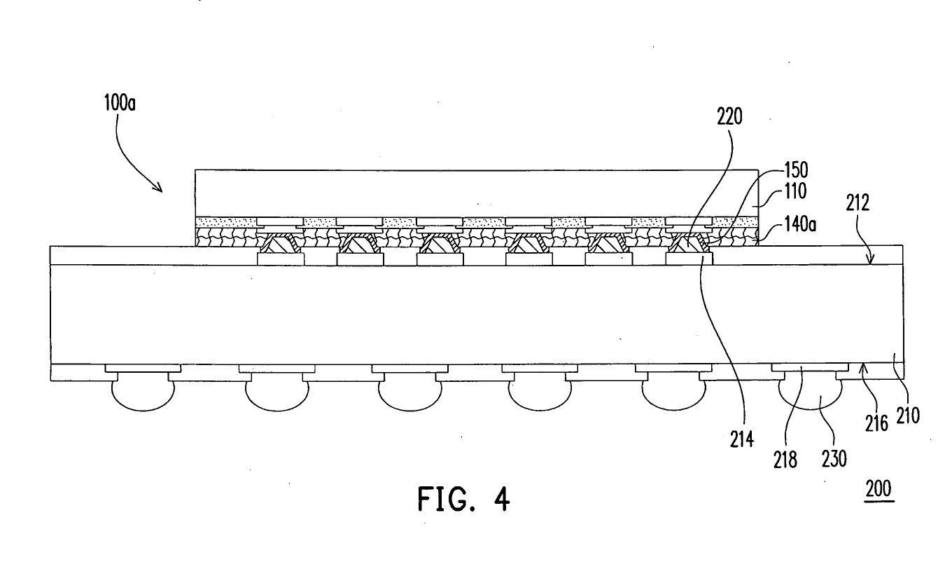

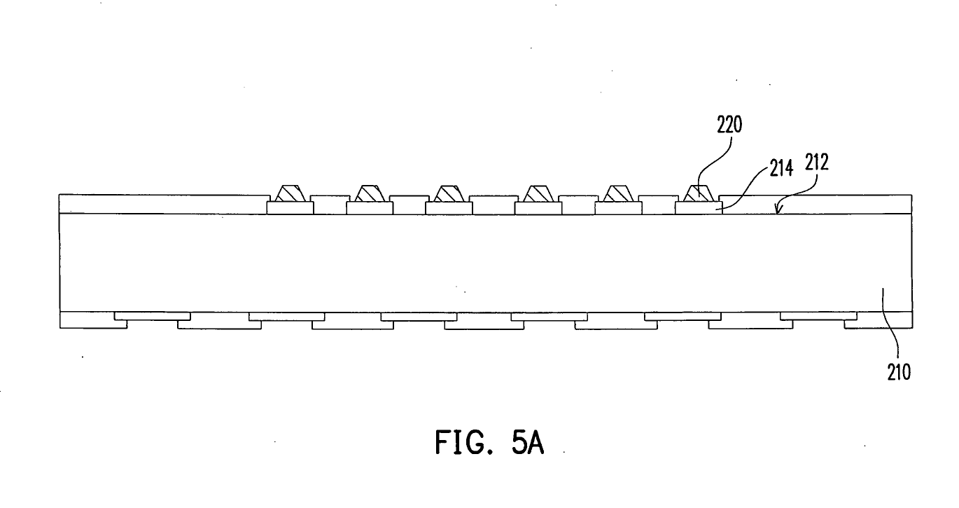

FIG. 4 schematically illustrates, in a cross-sectional view, a flip chip package structure according to the third embodiment of the present invention. A flip chip package structure includes a substrate 210, at least one solder bump 220 and a chip structure 100a. The substrate 210 has a carrying surface 212. At least one contact pad 214 is disposed on the carrying surface 212. The solder bump 220 is disposed on the contact pad 214 of the substrate 210. The solder bump 220 is a soldering tin, for example.

The chip structure 100a is disposed on the carrying surface 212 of the substrate 210. The chip structure 100a of the third embodiment is similar to the chip structure 100 of the first embodiment. The main difference is that the first dielectric layer 140 of the chip structure 100 is in the state of B-stage while the first dielectric layer 140a of the chip structure 100a is in the state of C-stage. That is, the chip structure 100a can be bonded to the substrate 210 securely by the C-stage first dielectric layer 140a. In addition, the first dielectric layer 140a is configured to prevent the problem of being cracked laterally between the chip structure 100a and the substrate 210; thus, a conventional underfill layer is not required.

Furthermore, the solder bump 220 is inlaid into the concave structure formed by the first conductive layer 150. In this embodiment, the chip 110 can be bonded to the substrate 210 via the first dielectric layer 140a; thus, the bonding effect between the first conductive layer 150 and the solder bump 220 is not required, as long as the first conductive layer 150 and the solder bump 220 can be electrically connected with each other. In another embodiment (not shown), a conductive adhesive, such as silver paste or anisotropic conductive paste, is disposed between the first conductive layer 150 and the solder bump 220 to provide the bonding effect. In another embodiment (not shown), the bonding effect can be generated from the metal diffusion reaction between the first conductive layer 150 and the solder bump 220.

### The Fourth Embodiment

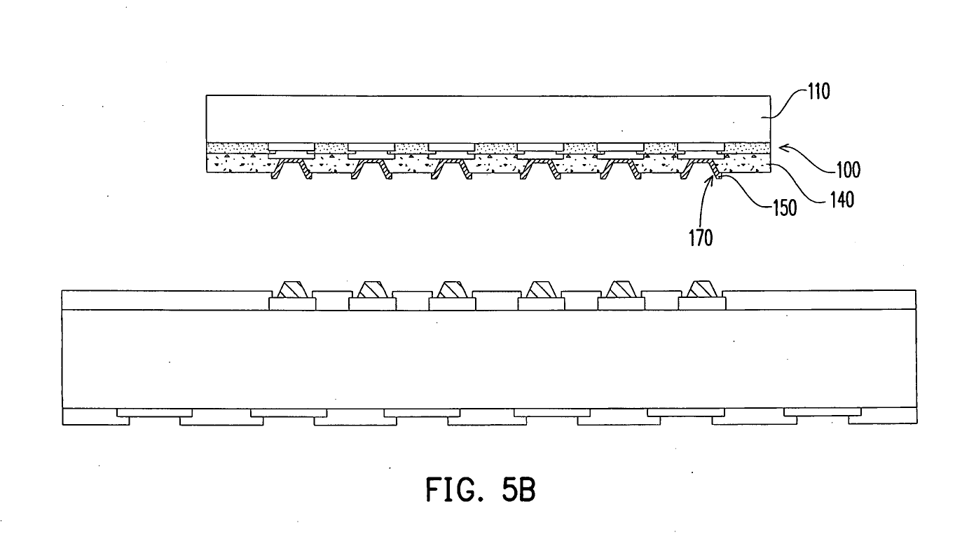

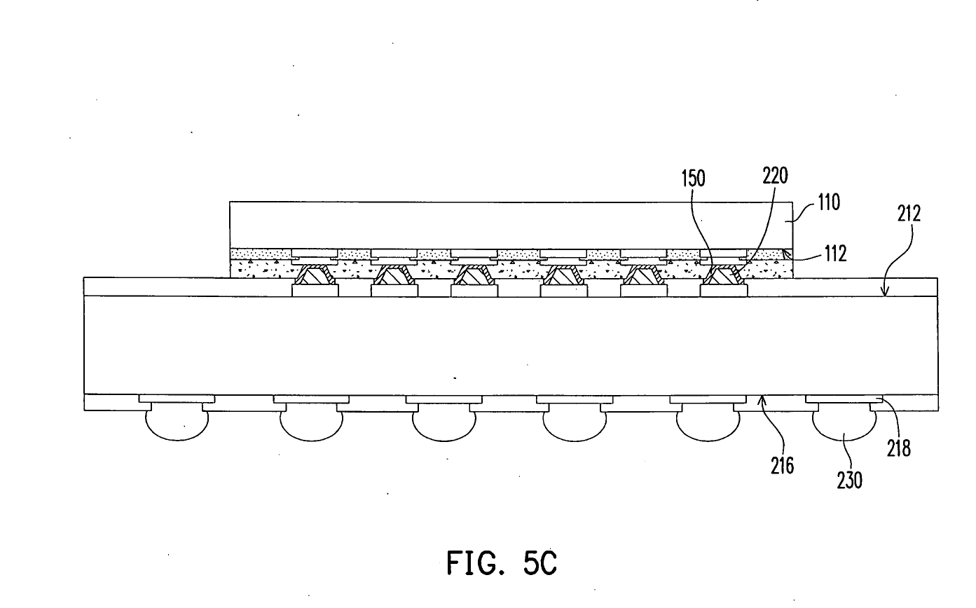

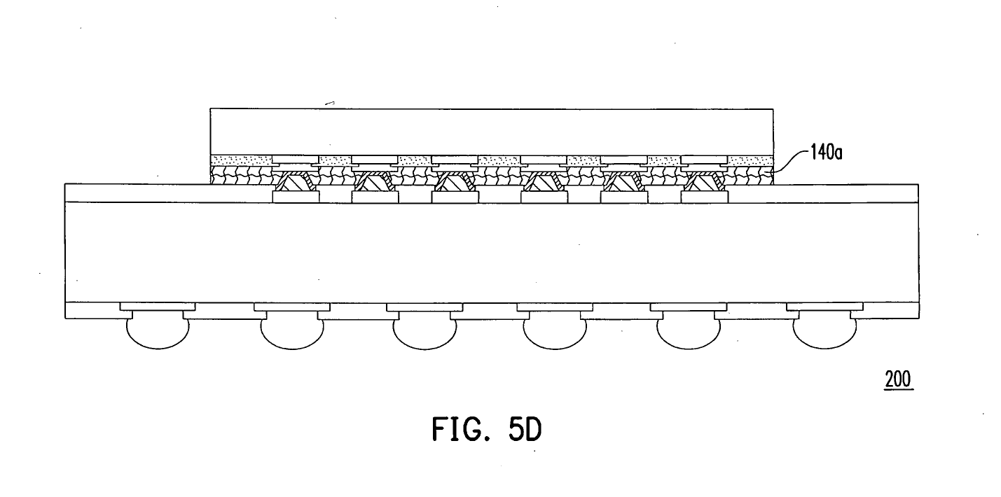

FIGS. 5A to 5D schematically illustrate, in a cross-sectional view, a fabrication process of a flip chip package structure according to the fourth embodiment of the present invention. In this embodiment, the flip chip package structure 200 of FIG. 4 is intended to illustrate and give no limitation to the present invention. First, referring to FIG. 5A, a substrate 210 having a carrying surface 212 is provided. The material of the substrate 210 includes ceramics or resin, for example. At least one contact pad 214 is disposed on the carrying surface 212 of the substrate 210, and a solder bump 220 is disposed on the contact pad 214. Thereafter, referring to FIG. 5B, a chip structure 100 of the first embodiment is provided. The chip structure 100 includes a chip 110, a first dielectric layer 140 and a concave structure 170 formed by the first conductive layer 150.

Referring to FIG. 5C, the active surface 112 of the chip 110 is disposed toward the carrying surface 212 of the substrate 210 so that the solder bump 220 is inlaid into the concave structure 170 (as shown in FIG. 5B) formed from the first conductive layer 150. The material of the solder bump 220 is a soldering tin or a lead-free material, for example. Thereafter, a plurality of solder balls 230 are formed on the contact pads 218 on the other side 216 of the substrate 210. The solder balls 230 can be connected to a circuit board (not shown).

Moreover, in another embodiment (not shown), before the active surface 112 of the chip 110 is disposed toward the carrying surface 212 of the substrate 210, a conductive adhesive is disposed between the first conductive layer 150 and the solder bump 220. Therefore, the first conductive layer 150 can be bonded to the solder bump 220 securely by the conductive adhesive. The conductive adhesive includes silver paste or anisotropic conductive paste, for example.

Referring to FIG. 5D, the first dielectric layer 140 is cured to finish the fabrication process of the flip chip package structure 200. In this embodiment, the first dielectric layer 140 is a B-stage dielectric layer including polyimide (PI), epoxy resin and Ajinomoto buildup film (ABF), for example. That is, the B-stage first dielectric layer 140 is transformed into the C-stage first dielectric layer 140a by heating the first dielectric layer 140. The chip 110 can be bonded to the substrate 210 via the first dielectric layer 140a; thus, the bonding effect between the first conductive layer 150 and the solder bump 220 is not required, as long as the first conductive layer 150 and the solder bump 220 can be electrically connected with each other. That is, the solder reflow temperature is not required, as long as the heating temperature is high enough to transform the B-stage first dielectric layer 140 into the C-stage first dielectric layer 140a. Therefore, the processing temperature in accordance with the present invention is lower than the conventional solder reflow temperature.

The temperature for heating the aforementioned B-stage first dielectric layer 140 ranges from 25 to 200 degrees centigrade, such as 150 degrees centigrade, for example. In another embodiment (not shown), the material of the first dielectric layer 140 is a UV-cured resin, so the first dielectric layer 140 can be cured by irradiating UV light.

Furthermore, when the first conductive layer 150 is bonded to the solder bump 220, the metal diffusion reaction is occurred if the first conductive layer 150 is formed from a metal material. That is, an inter-metal layer (not shown) is formed between the first conductive layer 150 and the solder bump 220 so that the bonding reliability between the first conductive layer 150 and the solder bump 220 is increased. For example, the inter-metal layer is formed between copper-tin, nickel-tin, aurum-tin or n-tin.

### The Fifth Embodiment

This embodiment illustrates applying the package structure of third embodiment to form a light emitting/receiving device 360. In this embodiment, the part of the package structure similar to the third embodiment should be derived from the third embodiment for persons skilled in the art. Please also refer to the fourth embodiment for the fabrication process of the package structure of the light emitting/receiving device 300. It is noted that these embodiments are intended to illustrate and give no limitation to the present invention. The difference between these embodiments is described in the following.

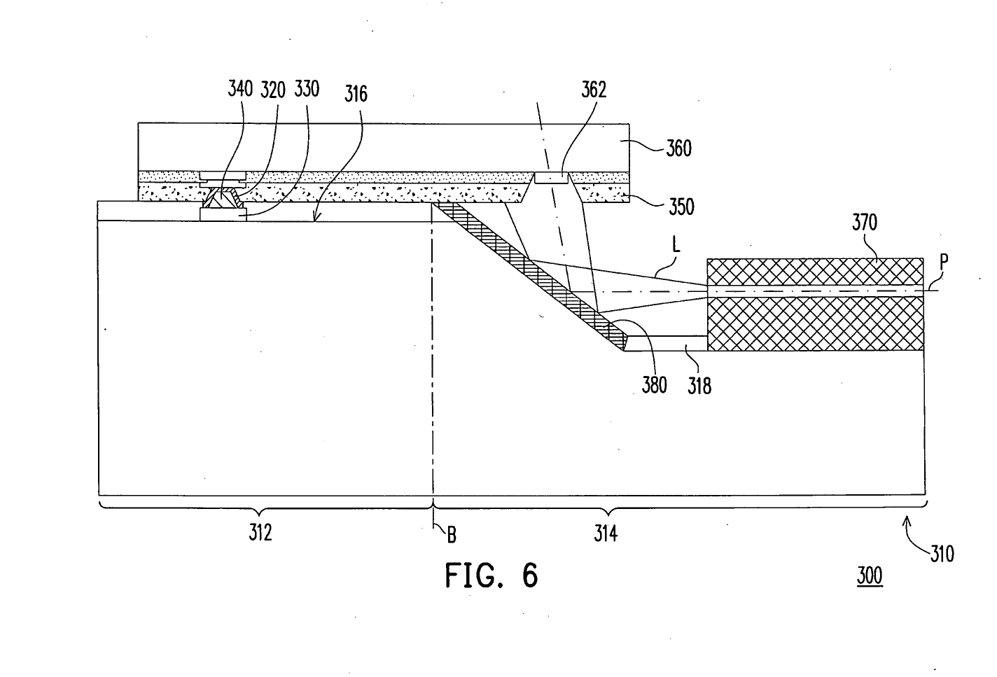

FIG. 6 schematically illustrates, in a cross-sectional view, a package structure of a light emitting/receiving device according to the fifth embodiment of the present invention. Referring to FIG. 6, a package structure of a light emitting/receiving device 300 mainly includes a substrate 310 and a light emitting/receiving device 360. The substrate 310 has a first portion 312 and a second portion 314. The first portion 312 has a carrying surface 316 to carry the light emitting/receiving device 360. In this embodiment, the virtual borderline B in FIG. 6 denotes the border between the first portion 312 and the second portion 314.

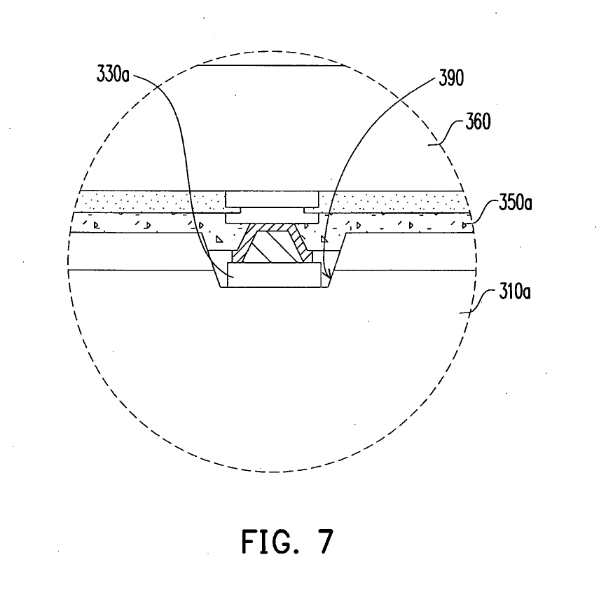

The solder bump 340 is inlaid into the concave structure formed by the first conductive layer 320 so that the light emitting/receiving device 360 is electrically connected with the substrate 310. In this embodiment, the contact pad 330 is disposed on the carrying surface 316, and the first dielectric layer 350 is contacted tightly with the substrate 310. FIG. 7 schematically illustrates, in a cross-sectional view, the inlaying between the solder bump and the first conductive layer according to another embodiment. In another embodiment, referring to FIG. 7, the substrate 310a further includes at least one recessed region 390, and the contact pad 330a is disposed on the bottom of the recessed region 390. The first dielectric layer 350a is inlaid into the recessed region 390 and contacted tightly with the substrate 310a after the process of compression bonding.

Referring to FIG. 6, the light emitting/receiving device 360 has a light signal input/output region 362 for emitting or receiving light. In this embodiment, the package structure of the light emitting/receiving device 300 is a vertical-cavity surface emitting laser (VCSEL), and the light emitting/receiving device 360 is a photo detector to detect the incident light L, for example. In another embodiment (not shown), the light emitting/receiving device 360 may be a laser source to generate a laser beam.

The package structure of the light emitting/receiving device 300 may further include a first optical device 370 and a second optical device 380. The light emitting/receiving device 360, the first optical device 370 and the second optical device 380 are disposed on the same optical path P. The second optical device 380 is disposed between the light emitting/receiving device 360 and the first optical device 370. In this embodiment, the first optical device 370 is an optical fiber and the second optical device 380 is a reflection mirror, for example. The light L is emitted from the first optical device 370 and transmitted to the second optical device 380. Thereafter, the light L is reflected by the second optical device 380 and then irradiates the light signal input/output region 362.

In terms of the disposition of the first optical device 370 and the second optical device 380 respect with respect to the substrate 310, the first optical device 370 and the second optical device 380 are disposed on the second portion 314. In this embodiment, the second portion 314 has a V-shape groove 318 and the first optical device 370 is disposed in the V-shape groove 318.

### The Sixth Embodiment

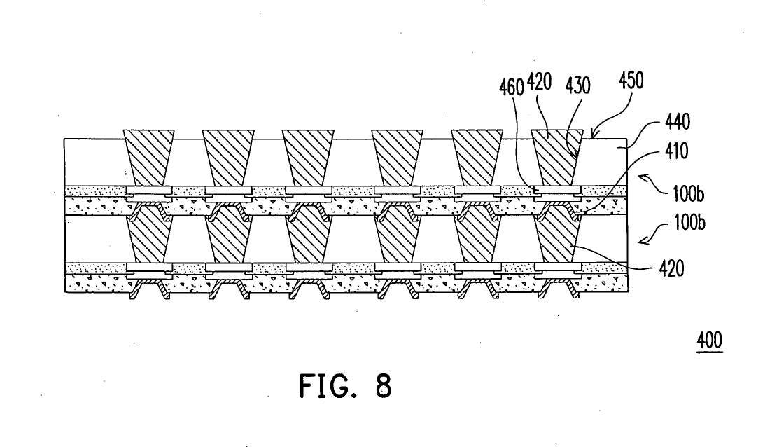

FIG. 8 schematically illustrates, in a cross-sectional view, a chip stacked structure according to the sixth embodiment of the present invention. Referring to FIG. 8, the chip stacked structure includes a plurality of chip structures 100b, and the chip structures 100b are stacked together. Each chip structure 100b is similar to the chip structure 100 of the first embodiment. The main difference is that at least one third opening 430 is formed in the backside 450 of the chip 440 for each chip structure 100b, so as to expose the bonding pad 460. Conductive pillars 420 are formed respectively in the third openings 430, and the conductive pillars 420 are connected to the corresponding bonding pads 460. Two adjacent chip structures 100b (as shown in FIG. 8) are stacked and bonded via the corresponding concave structure 410 and the corresponding conductive pillar 420.

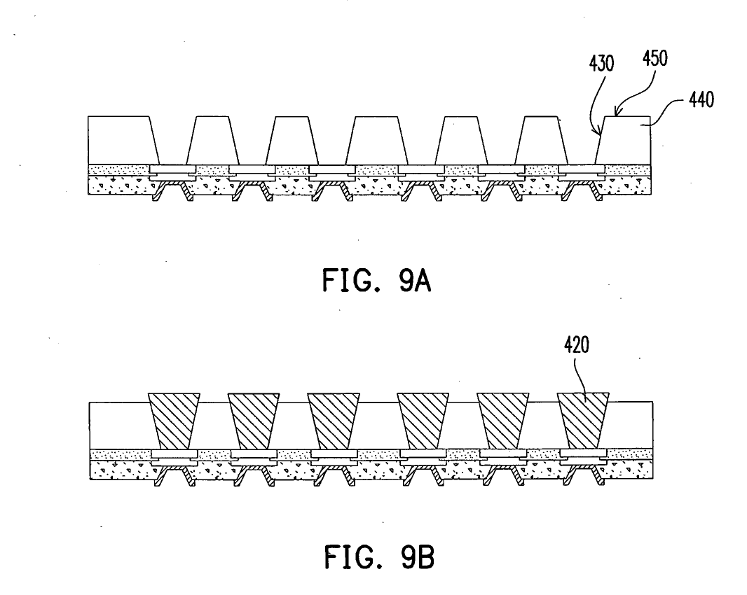

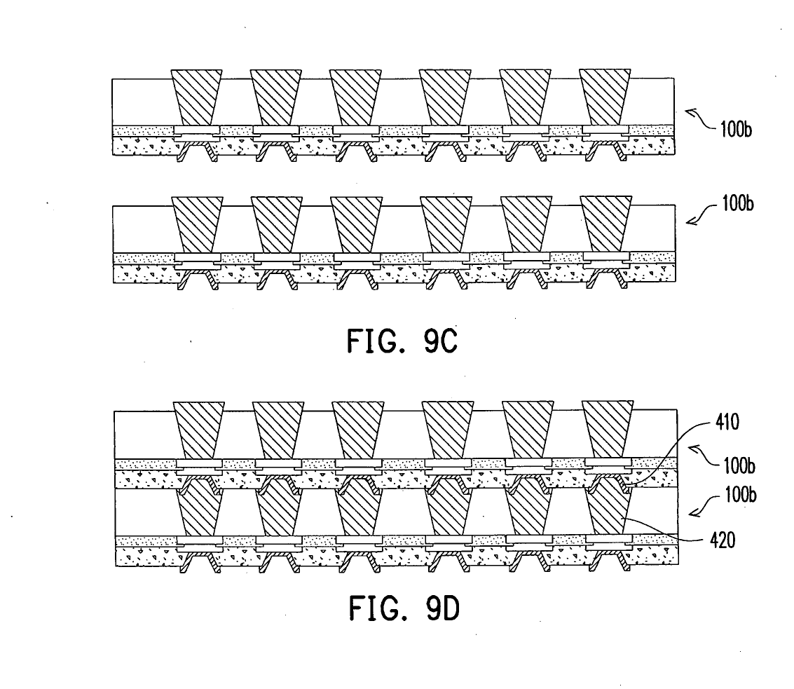

FIGS. 9A to 9D schematically illustrate, in a cross-sectional view, a fabrication process of the chip stacked structure of FIG. 8. After the fabrication process of the second embodiment (as shown in FIGS. 3A to 3K), the following processing steps are implemented. First, referring to FIG. 9A, at least one third opening 430 is formed in the chip 440 by laser-drilling. Referring to FIG. 9B, a conductive adhesive such as tin paste or silver paste is filled into the third openings 430, so that a plurality of conductive pillars 420 are formed to connect the corresponding bonding pads 460 respectively. After being fabricated, referring to FIG. 9C, the chip structures 100b are stacked together by connecting the concave structures 410 to the corresponding conductive pillars 420.

In summary, according to the chip structure of the present invention, the conventional solder bumps formed on the bonding pads of the chip are not required; thus, the structure is simpler and the cost of fabricating the conventional solder bumps is saved. In addition, the problem that the dimension of the conventional solder bumps affects the pitch between the bonding pads is avoided; hence, the pitch between the bonding pads can be further reduced so that the integration of bonding pads is increased.

Moreover, according to the fabrication process of the flip chip package structure of the present invention, the solder bumps of the substrate are inlaid into the concave structures of the chip without performing the conventional solder reflow process, and thus a lower process temperature is resulted. The present invention can also apply to a cordless substrate. The warpage of the cordless substrate during the solder reflow process is avoided because no solder reflow process is performed. Also, according to the flip chip package structure of the present invention, the chip can be bonded to the substrate by the first dielectric layer so that no gap exists between the chip and the substrate; hence, a conventional underfill layer is not required and the shorter processing time and lower processing cost are resulted.

Moreover, according to the package structure of the light emitting/receiving device of the present invention, no gap exists between the light emitting/receiving device and the substrate because the light emitting/receiving device is contacted tightly with the substrate by the first dielectric layer, so that the light emitting/receiving device is bonded to the substrate more securely; thus, the reliability of the package structure of the light emitting/receiving device is enhanced. In addition, according to the chip stacked structure of the present invention, a plurality of chip structures are stacked together by the inlaying between the concave structures and the conductive pillars in the backside. When fabricating the chip stacked structure, only a compression bonding process is required to stack and bond the chip structures. Therefore, the structure is simpler, the fabrication process is simplified, and the processing cost is reduced.

The present invention has been disclosed above in the preferred embodiments, but is not limited to those. It is known to persons skilled in the art that some modifications and innovations may be made without departing from the spirit and scope of the present invention. Hence, the scope of the present invention should be defined by the following claims.

What is claimed is:

1. A chip structure, comprising:
a chip, having an active surface, a backside and at least one bonding pad, wherein the bonding pad is disposed on the active surface;
a first dielectric layer, disposed on the active surface and having at least one first opening, wherein the first opening correspondingly exposes the bonding pad; and
at least one first conductive layer, covering an inner wall of the first opening and the bonding pad so as to form a concave structure in the first opening.

2. The chip structure of claim 1, further comprising a second dielectric layer disposed between the active surface and the first dielectric layer and having at least one second opening, wherein the second opening correspondingly exposes the bonding pad.

3. The chip structure of claim 2, wherein a moisture absorption rate of the second dielectric layer is higher than a moisture absorption rate of the first dielectric layer.

4. The chip structure of claim 3, wherein a dielectric constant of the second dielectric layer is smaller than a dielectric constant of the first dielectric layer.

5. The chip structure of claim 1, wherein the first dielectric layer is a B-stage dielectric layer.

6. The chip structure of claim 1, further comprising at least one second conductive layer disposed between the first conductive layer and the bonding pad.

7. The chip structure of claim 1, wherein the backside of the chip has at least one third opening to expose the bonding pad, the chip structure further comprising at least one conductive pillar disposed in the third opening and connected to the bonding pad.

8. A fabrication process of a chip structure, comprising:
providing a chip, the chip having an active surface, a backside, and at least one bonding pad, wherein the bonding pad is disposed on the active surface;
forming a first dielectric layer on the active surface of the chip;
forming at least one first opening in the first dielectric layer, wherein the first opening correspondingly exposes the bonding pad; and
forming at least one first conductive layer on an inner wall of the first opening and the bonding pad so as to form a concave structure in the first opening.

9. The fabrication process of claim 8, wherein the step of forming the first conductive layer on the bonding pad comprises:
forming an electroplating seeding layer on the first dielectric layer;
forming a patterned photoresist layer on the electroplating seeding layer, wherein the patterned photoresist layer exposes a portion of the electroplate seeding layer corresponding to the first opening;
performing an electroplating process to the electroplate seeding layer by using the patterned photoresist layer as a mask;
removing the patterned photoresist layer; and
removing the portion of the electroplating seeding layer covered by the patterned photoresist layer.

10. The fabrication process of claim 8, further comprising forming a second dielectric layer on the active surface before forming the first dielectric layer, wherein the second dielectric layer has at least one second opening to correspondingly expose the bonding pad.

11. The fabrication process of claim 8, wherein the first dielectric layer is a B-stage dielectric layer.

12. The fabrication process of claim 8, further comprising forming at least one second conductive layer on the bonding pad before forming the first dielectric layer.

13. The fabrication process of claim 8, further comprising:
forming at least one third opening in the backside, wherein the third opening correspondingly exposes the bonding pad; and
forming at least one conductive pillar in the third opening, wherein the conductive pillar is connected to the bonding pad.

14. A flip chip package structure, comprising:
a substrate, having a carrying surface and at least one contact pad disposed on the carrying surface;
at least one solder bump, disposed on the contact pad of the substrate;
a chip, disposed on the carrying surface and comprising an active surface and at least one bonding pad, wherein the bonding pad is disposed on the active surface and corresponds to the solder bump;
a first dielectric layer, disposed between the chip and the substrate and having at least one first opening, wherein the first opening correspondingly exposes the bonding pad of the chip; and
at least one first conductive layer, covering an inner wall of the first opening and the bonding pad so as to form a concave structure in the first opening, wherein the solder bump is inlaid into the concave structure.

15. The flip chip package structure of claim 14, further comprising at least one inter-metal layer disposed between the first conductive layer and the solder bump.

16. The flip chip package structure of claim 14, further comprising a conductive adhesive disposed between the first conductive layer and the solder bump.

17. The flip chip package structure of claim 14, further comprising a second dielectric layer disposed between the active surface and the first dielectric layer and having at least one second opening, wherein the second opening correspondingly exposes the bonding pad.

18. The flip chip package structure of claim 17, wherein a moisture absorption rate of the second dielectric layer is higher than a moisture absorption rate of the first dielectric layer.

19. The flip chip package structure of claim 17, wherein a dielectric constant of the second dielectric layer is smaller than a dielectric constant of the first dielectric layer.

20. The flip chip package structure of claim 14, wherein the first dielectric layer is a C-stage dielectric layer.

21. The flip chip package structure of claim 14, further comprising at least one second conductive layer disposed between the first conductive layer and the bonding pad.

22. A fabrication process of a flip chip package, comprising:
providing a chip, the chip having an active surface and at least one bonding pad, wherein the bonding pad is disposed on the active surface;
forming a first dielectric layer on the active surface of the chip;
forming at least one first opening in the first dielectric layer, wherein the first opening exposes the bonding pad;
forming at least one first conductive layer on an inner wall of the first opening and the bonding pad so as to form a concave structure in the first opening;
providing a substrate, the substrate having a carrying surface, wherein at least one contact pad is disposed on the carrying surface and a solder bump is disposed on the contact pad;
disposing the active surface of the chip toward the carrying surface of the substrate so that the solder bump is inlaid into the concave structure; and
curing the first dielectric layer.

23. The fabrication process of claim 22, wherein the first dielectric layer is a B-stage dielectric layer.

24. The fabrication process of claim 23, wherein the step of curing the first dielectric layer comprises heating the first dielectric layer so that a state of the first dielectric layer is transformed from B-stage to C-stage.

25. The fabrication process of claim 22, wherein the step of forming the first conductive layer on the bonding pad comprises:
forming an electroplating seeding layer on the first dielectric layer;
forming a patterned photoresist layer on the electroplating seeding layer so as to expose a portion of the electroplate seeding layer corresponding to the first opening;
performing an electroplating process to the electroplate seeding layer by using the patterned photoresist layer as a mask;
removing the patterned photoresist layer; and
removing the portion of the electroplating seeding layer covered by the patterned photoresist layer.

26. The fabrication process of claim 22, further comprising forming a second dielectric layer on the active surface before forming the first dielectric layer, wherein the second dielectric layer has at least one second opening to correspondingly expose the bonding pad.

27. The fabrication process of claim 22, further comprising forming at least one second conductive layer on the bonding pad before forming the first dielectric layer, so that the second conductive layer is electrically connected to the bonding pad.

28. The fabrication process of claim 22, further comprising disposing a conductive adhesive between the first conductive layer and the solder bump before disposing the active surface of the chip toward the carrying surface of the substrate.

29. A package structure, comprising:
a substrate, having a first portion and the second portion, wherein the first portion has a carrying surface and at least one contact pad disposed on the carrying surface;
at least one solder bump, disposed on the contact pad of the substrate;
a light emitting/receiving device, disposed on the active surface and having an active area, at least one bonding pad and a light signal input/output region, wherein the bonding pad is disposed on the active area and corresponds to the solder bump, and the light signal input/output region is used for emitting or receiving light and corresponds to the second portion;
a first dielectric layer, disposed between the light emitting/receiving device and the substrate and having at least one first opening, wherein the first opening correspondingly exposes the bonding pad of the light emitting/receiving device; and
at least one first conductive layer, covering an inner wall of the first opening and the bonding pad so as to form a concave structure, wherein the solder bump is inlaid into the concave structure.

30. The package structure of claim 29, wherein the substrate further comprises at least one recessed region, and the contact pad is disposed on a bottom of the recessed region.

31. The package structure of claim 29, further comprising an optical fiber, wherein the optical fiber and the light emitting/receiving device are both disposed in an optical path.

32. The package structure of claim 31, wherein the second portion comprises a V-shape groove and the optical fiber is disposed in the V-shape groove.

33. The package structure of claim 31, further comprising a reflection mirror disposed on the second portion, wherein the reflection mirror is on the optical path between the light emitting/receiving device and the optical fiber.

34. The package structure of claim 29, further comprising at least one inter-metal layer disposed between the first conductive layer and the solder bump.

35. The package structure of claim 29, further comprising a conductive adhesive disposed between the first conductive layer and the solder bump.

36. The package structure of claim 29, further comprising a second dielectric layer disposed between the active surface and the first dielectric layer and having at least one second opening, wherein the second opening correspondingly exposes the bonding pad.

37. The package structure of claim 36, wherein a moisture absorption rate of the second dielectric layer is higher than a moisture absorption rate of the first dielectric layer.

38. The package structure of claim 36, wherein a dielectric constant of the second dielectric layer is smaller than a dielectric constant of the first dielectric layer.

39. The package structure of claim 29, wherein the first dielectric layer is a C-stage dielectric layer.

40. The package structure of claim 29, further comprising at least one second conductive layer disposed between the first conductive layer and the bonding pad.

41. A chip stacked structure, comprising:
a plurality of chip structures, wherein each of the chip structures comprises:
a chip, having an active surface, a backside, at least one third opening and at least one bonding pad, wherein the bonding pad is disposed on the active surface and the third opening is disposed in the backside to expose the bonding pad;
a first dielectric layer, disposed on the active surface and having at least one first opening, wherein the first opening correspondingly exposes the bonding pad;
at least one first conductive layer, covering an inner wall of the first opening and the bonding pad so as to form a concave structure in the first opening; and
at least one conductive pillar, disposed in the third opening and connected to the bonding pad,
wherein the chip structures are stacked together, and each two adjacent chip structures are bonded together via the corresponding concave structure and the corresponding conductive pillar.

42. The chip stacked structure of claim 41, wherein each chip structure further comprises a second dielectric layer disposed between the active surface and the first dielectric layer and having at least one second opening, and the second opening correspondingly exposes the bonding pad.

43. The chip stacked structure of claim 42, wherein, for each chip structure, a moisture absorption rate of the second dielectric layer is higher than a moisture absorption rate of the first dielectric layer.

44. The chip stacked structure of claim 42, wherein, for each chip structure, a dielectric constant of the second dielectric layer is smaller than a dielectric constant of the first dielectric layer.

45. The chip stacked structure of claim 41, wherein the first dielectric layer of each chip structure is a C-stage dielectric layer.

46. The chip stacked structure of claim 41, wherein each chip structure further comprises at least one second conductive layer disposed between the corresponding first conductive layer and the corresponding bonding pad.
